(19) United States
(12) Patent Application Publication
(10) Pub. No.: US 2025/0383311 A1
(43) Pub. Date: Dec. 18, 2025

(54) SPEAKER SENSOR SYSTEM AND METHOD

(71) Applicant: Purdue Research Foundation, West Lafayette, IN (US)

(72) Inventor: Noori Kim, West Lafayette, IN (US)

(73) Assignee: Purdue Research Foundation, West Lafayette, IN (US)

(21) Appl. No.: 19/232,714

(22) Filed: Jun. 9, 2025

Related U.S. Application Data
(60) Provisional application No. 63/659,484, filed on Jun. 13, 2024.

(51) Int. Cl. G01N 27/12; G01N 27/04; G01R 27/26

(52) U.S. Cl. CPC G01N 27/128; G01N 27/048; G01N 27/122; G01R 27/26

(57) ABSTRACT

A method of measuring characteristics of a cavity using an electroacoustic transducer (ET) includes inserting an ET having at least two electrical terminals into a proximal end of a cavity having a distal end defining a termination body, wherein the ET is configured to i) operate in a speaker mode thereby generating sound waves when an electrical signal is provided across the at least two electrical terminals, and ii) operate in a sensor mode when measuring impedance across the at least two electrical terminals, operating the ET in the speaker mode by applying an electrical signal across the at least two electrical terminals, operating the ET in the sensor mode by measuring impedance across the at least two electrical terminals, providing the measured impedance to a neural network configured to correlate impedance measurements of the ET to cavity characteristics, and predicting cavity characteristics based on output of the neural network.

### CROSS-REFERENCE TO RELATED APPLICATIONS

The present non-provisional patent application is related to and claims the priority benefit of U.S. Provisional Patent Application Ser. 63/659,484, filed Jun. 13, 2024, the contents of which are hereby incorporated by reference in its entirety into the present disclosure.

### STATEMENT REGARDING GOVERNMENT FUNDING

None.

### TECHNICAL FIELD

The present disclosure generally relates to transducers and in particular to a transducer system and method utilized to determine characteristics of a cavity when the transducer is operated in dual modes.

### BACKGROUND

This section introduces aspects that may help facilitate a better understanding of the disclosure. Accordingly, these statements are to be read in this light and are not to be understood as admissions about what is or is not prior art.

In acoustic research, two critical devices play pivotal roles: microphones and speakers. Typically, microphones are used as sensors to capture acoustic signals, while speakers act as actuators to generate sounds. Speakers in the form of headphones, or more specifically, earphones or in-ear headphones, are commonplace nowadays. These devices may be wired or wireless. Regardless, each earphone may include two terminals adapted to receive electrical signals applied thereto. The electrical signal is converted to sound by the electroacoustic transducer that is part of the earphone.

It is commonplace for individuals who work in loud auditory places to have their hearing checked from time-to-time to monitor hearing loss. A hearing assessment often requires insertion of a probe into an ear canal to provide various testing sounds. When a probe is inserted into the ear canal, the distance between the probe and the eardrum, typically referred to as the insertion depth, is important. However, there are no easy ways to establish this distance. While hearing assessment is one such application, when placing a probe inside a cavity that is terminated by a termination body, it is often important to determine the distance between the probe and the termination body. However, the solution to this problem remains elusive.

Thus, there is an unmet need for a novel approach to determine characteristics of a cavity defined by a termination body, when an electroacoustic transducer with a sound probe is inserted into the cavity.

### SUMMARY

A method of measuring characteristics of a cavity using an electroacoustic transducer is disclosed. The method includes inserting an electroacoustic transducer having at least two electrical terminals and a sound port into a proximal end of a cavity having a distal end defining a termination body. The electroacoustic transducer is configured to i) operate in a speaker mode thereby generating sound waves when an electrical signal is provided across the at least two electrical terminals, and ii) operate in a sensor mode when measuring impedance across the at least two electrical terminals. The method further includes operating the electroacoustic transducer in the speaker mode by applying an electrical signal having a predetermined frequency range across the at least two electrical terminals, operating the electroacoustic transducer in the sensor mode by measuring impedance across the at least two electrical terminals in response to the applied electrical signal, providing the measured impedance to a neural network, wherein the neural network has been a priori trained to correlate impedance measurements of the electroacoustic transducer to cavity characteristics, and predicting cavity characteristics based on output of the neural network.

A system for measuring characteristics of a cavity using an electroacoustic transducer is also disclosed. The system includes an electroacoustic transducer having at least two electrical terminals and a sound port. The electroacoustic transducer is configured to i) operate in a speaker mode thereby generating sound waves when providing an electrical signal across the at least two electrical terminals, and ii) operate in a sensor mode when measuring impedance across the at least two electrical terminals. The system also includes a processor executing software maintained in a non-transitory memory. The processor configured to generate a signal that is applied across the at least two electrical terminals of the electroacoustic transducer when the electroacoustic transducer is inserted into a proximal end of a cavity having a distal end defining a termination body, wherein the electroacoustic transducer is operated in the speaker mode, measure impedance across the at least two electrical terminals of the electroacoustic transducer, wherein the electroacoustic transducer is operated in the sensor mode in response to the applied signal, provide the measured impedance to a neural network, wherein the neural network has been a priori trained to correlate impedance measurements of the electroacoustic transducer to cavity characteristics, and predict cavity characteristics based on output of the neural network.

### BRIEF DESCRIPTION OF FIGURES

FIG. 1 is a diagram of a setup used according to the present disclosure including a syringe, and a speaker disposed in the syringe.

FIG. 2 is a schematic of electrical components of the experimental setup.

FIG. 3 is a schematic of the complete experimental setup which allowed for precise and consistent frequency sweeps spanning the human auditory range, from 20 Hz to 20 kHz, with 501 linearly spaced frequency points per sweep.

FIG. 4 is a flowchart that shows the flow of a neural network training and evaluation processes, according to the present disclosure.

FIGS. 5a-5d are graphs of magnitude vs. frequency graphs for various speaker groups shown in Table 1.

FIGS. 6a-6d are graphs of phase vs. frequency graphs for various speaker groups shown in Table 1.

FIGS. 7a-7d are graphs of true labels vs. predicted labels in a confusion matrix showing accuracy of the neural network for different speaker groups as provided in Table 1.

FIG. 8 is a graph of true label vs. predicted label for length only in a confusion matrix showing accuracy of the neural network for different insertion depths.

FIGS. 9a-9d are graphs of true label vs. predicted label for speaker groups A-D, respectively, in a confusion matrix.

FIG. 10 provides graphs of magnitude and phase of the impedance measurements (resulting from real part, i.e., resistance, R; and the imaginary part, i.e., the reactance, X), for two levels of relative humidity.

FIGS. 11a and 11b are graphs of magnitude and phase, respectively, of the measured impedance for two different temperatures for 22.8° C. and 30.2° C.

FIGS. 12a and 12b provide magnitude and phase of impedance measurements, respectively, under various conditions (open, blocked, and an insertion depth of 17 mm) for ambient noise of about 39 dB and about 79 dB.

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

In the present disclosure, the term “about” can allow for a degree of variability in a value or range, for example, within 15%, within 10%, within 5%, or within 1% of a stated value or of a stated limit of a range.

In the present disclosure, the term “substantially” can allow for a degree of variability in a value or range, for example, within 85%, within 90%, within 95%, or within 99% of a stated value or of a stated limit of a range.

A novel approach is disclosed herein to determine characteristics of a cavity defined by a termination body, when an electroacoustic transducer with a sound probe is inserted into the cavity. Towards this end, the present disclosure describes use of impedance measurements when the electroacoustic transducer is energized to determine the characteristics of the cavity. The impedance measurements, according to the present disclosure, are provided to a neural network trained to correlate impedance measurements to the cavity characteristics in order to output expected said characteristics.

Impedance represents opposition to flow of alternating current (AC) and includes both magnitude and phase, represented by a real part, typically referred to as resistance (R), and an imaginary part, typically referred to as reactance (X). Reactance is the result of phase changes due to lumped capacitance and inductance in the system. For example, the electroacoustic transducer includes a coil which can be expressed in terms of inductance. The characteristics of the cavity include such as i) insertion depth, ii) temperature of air between the sound probe and the termination body of the cavity, and iii) relative humidity of air between the sound probe and the termination body of the cavity. When the electroacoustic transducer is energized, the said characteristics of the cavity can make a change in impedance measurements at the electrical terminals of the transducer. Therefore, by measuring the impedance at the electrical terminals, one can correlate the impedance measurements to said characteristics of the cavity. The present disclosure describes an approach whereby this correlation is achieved by a neural network that is a priori trained to make this correlation. Therefore, the electroacoustic transducer is used both as an actuator in the form of a speaker, and as a sensor for measuring said cavity characteristics.

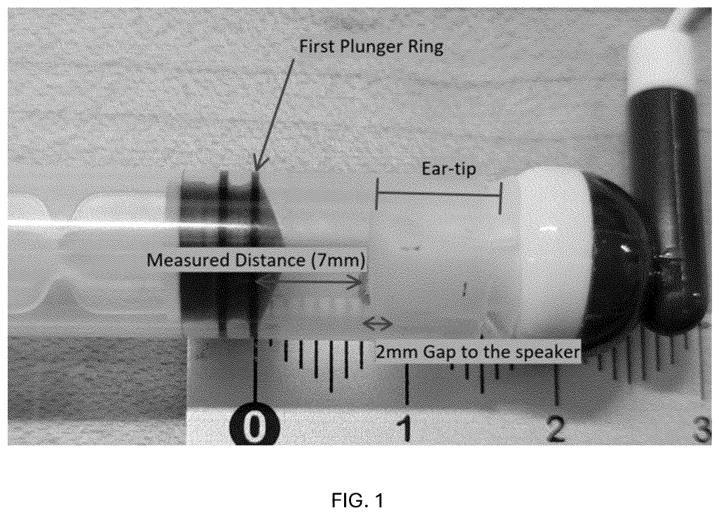

Electrical impedance measurements are conducted using the Analog Discovery 2 device, interfaced through the “Set-Up” Diligent WaveForms Workspace file. Both impedance and phase are measured across a frequency sweep spanning the human audio range (20 Hz-20 kHz) with a total of 501 points. The setup includes a 10002 load in series with the speaker being measured. The data acquisition process involves taking a single measurement to complete one sweep, exporting the data as a CSV file, and repeating this process for the desired number of samples. The sweep is repeated 50 times for each of the following insertion depths: blocked (i.e., the sound port of the electroacoustic transducer is blocked), 9 mm, 14 mm, 24 mm, 39 mm, and open (the electroacoustic transducer is outside of the cavity). Four speaker types were used that are listed in Table 1 below. To ensure a consistent fit within the syringe enclosure and to simulate speaker (earphone) insertion to human ears, the ear-tips were attached to the speakers' main body as shown in FIG. 1, which is a diagram of a setup used including a syringe, and a speaker disposed in the syringe. However, these ear-tips introduced a measurable gap between the ear-tip edge and the speaker grill, which was accounted for during measurements. The gaps, measured with a caliper, were approximated as shown in Table 1.

TABLE 1
Speaker types used according to the present disclosure

| | | Gap | Gap |
|---|---|---|---|
| Group | | measured | approximated |
| Identifier | Description | (mm) | (mm) |
| A | Generic airline provided | 2.83 | 3 |
| | (32.59 Ω) | | |
| B | Generic airline provided | 2.28 | 2 |
| | (31.18 Ω) | | |
| C | Sennheiser's CX80S wired | 2.12 | 2 |
| | earbuds (27.35 Ω) | | |
| D | Unbranded (33.18 Ω) | 1.98 | 2 |

Once the speakers were fit in the syringe, the enclosure length was adjusted to simulate different enclosure dimensions. A marker line on the syringe body was used as a reference for tip placement, and a ruler was employed to ensure accurate positioning, as shown in FIG. 1. For example, to achieve a 9 mm enclosure length for speaker D, the syringe plunger was set 7 mm from the marker line to account for the 2 mm gap.

To prevent measurement artifacts, the speakers were removed after each adjustment of the syringe plunger. Failure to do so could create air pressure changes in the syringe chamber that would alter acoustics, and hence the impedance readings.

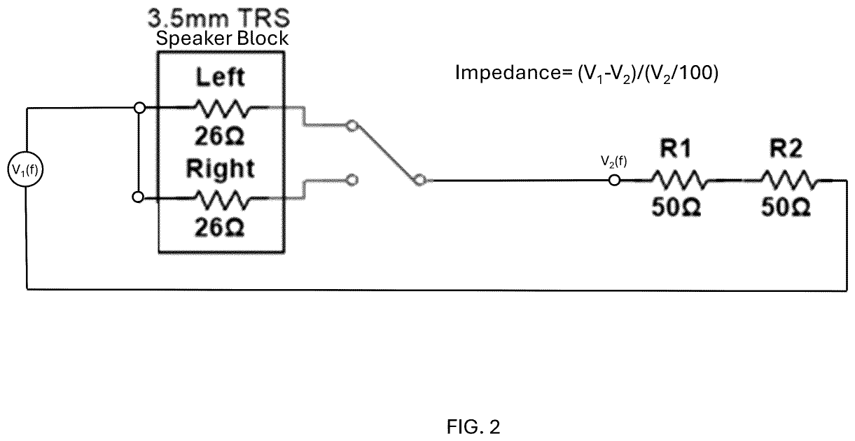

For connectivity, the measurement circuit featured a 3.5 mm standard audio Tip-Ring-Sleeve (TRS) input for stereo earbuds. A switch allowed selection between the left or right channel each representing a resistance based on the lumped resistance in the speaker, e.g., 26Ω, for the TRS connection. This flexibility ensured compatibility with various speaker configurations. FIG. 2 is a schematic of electrical components of the experimental setup. It should be noted that if only one speaker is connected at a time. However, if only one channel is used, then the speaker block and the connector are adjusted, accordingly.

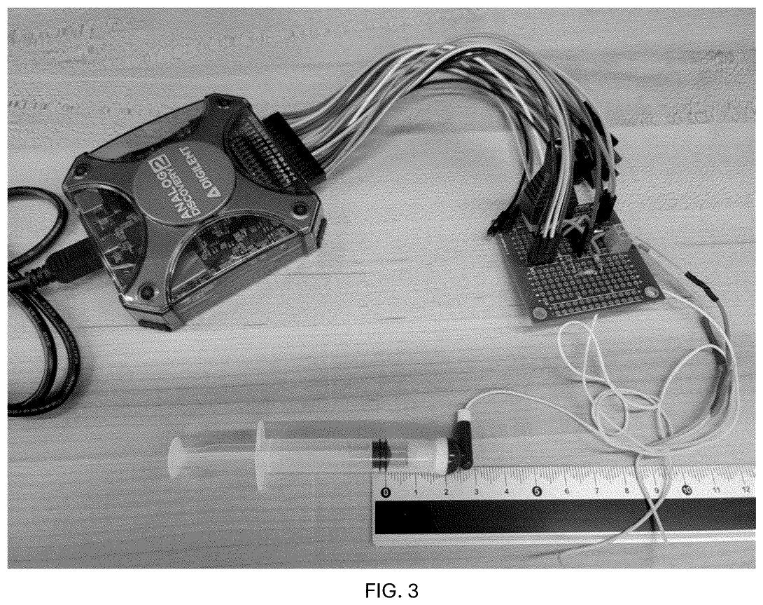

Impedance measurements were acquired using a Digilent Analog Discovery 2 device, controlled via WaveForms software. The setup shown is shown in FIG. 3 which is a schematic of the complete experimental setup which allowed for precise and consistent frequency sweeps spanning the human auditory range, from 20 Hz to 20 kHz, with 501 linearly spaced frequency points per sweep. While not explicitly shown in FIG. 3, one or more processors executing software maintained on a non-transitory memory are responsible for applying an electrical signal to the speaker with a sound probe inside the cavity and to measure impedance in response to the applied electrical signal. The electrical signal may be a sinusoidal tone signal with a constant amplitude and a sweeping frequency between 20 Hz and 20,000 Hz. A 100Ω load is connected in series with the device under test (DUT), serving as a reference for impedance calculations. This configuration is employed to analyze the speakers' impedance including magnitude and phase characteristics. The series load enables a more precise determination of the impedance magnitude and phase.

To streamline data collection, a custom graphical user interface (GUI) was developed using Tkinter in Python. This GUI interfaces with the Digilent Analog Discovery 2 device, automating file naming, measurement repetition, and dataset organization.

Data was collected for four distinct speakers across 14 enclosure lengths. Measurements were conducted at intervals of 3 mm from 5 mm to 29 mm, supplemented by additional key distances of 9 mm, 24 mm, and 39 mm, as well as Open and Blocked conditions. For each configuration, 100 runs were performed, resulting in a total dataset of 4 speakers*14 distances 100 runs=5600 total measurement files.

Each measurement sweep generated a CSV file. Each file comprises 501 data rows with the following fields as columns:
Frequency (Hz): Frequency of the measurement point for the sweep.
Phase (degrees in radian): Impedance phase angle at the frequency.
   |Z|(Ω): Impedance magnitude.
R (Ω): Real part of the impedance.
X (Ω): Reactive component of the impedance

Referring to FIG. 2, the impedance is measured based on (V₁−V₂)/(V₂/100), which has a real part and an imaginary part. Therefore, by measuring V₁ and V₂ impedance can be measured by specialized instruments such as an LCR meters or an impedance analyzer, as further discussed below. A sample of the dataset is shown in Table 2.

TABLE 2
Sample of dataset

| Frequency | Trace θ | Trace | Trace | Trace |
|---|---|---|---|---|
| (Hz) | (rad) | \|Z\| (Ω) | Rₛ (Ω) | Xₛ (Ω) |
| 20 | 0.0263 | 31.8526 | 31.8526 | 0.0488 |
| 59.96 | 0.0877 | 31.854 | 31.8539 | 0.075 |
| 99.92 | 0.1350 | 31.8599 | 31.8598 | 0.1048 |
| 139.88 | 0.1885 | 31.8526 | 31.8526 | 0.0488 |

In Table 2, representing sample of the dataset, there are five columns: the first column represents frequency of a tone; the second column represents phase of the impedance in Ω; the third column is the magnitude of the impedance in Ω; the fourth column is the real part of the impedance (i.e., resistance Rₛ measured in Ω); and the fifth column is the imaginary part of the impedance (i.e., reactance Xₛ measured in Ω). The fourth and furth columns are measured, while the second and third columns are calculated. The second column is determined based on Arctan of (Xₛ/Rₛ), example: Trace θ=Arctan (0.0488/318526)=0.0263, measured in rads. The third column is determined based on square root of the values in the fourth and fifth columns, example:

$$Trace \vert Z \vert = \sqrt{{31.8526}^{2} + {0.0488}^{2}} = 31.8526 ,$$

measured in Ω.

The dataset underwent relatively simple but a series of preprocessing steps before being used as input to the neural network. First, for each file, specific fields or columns are chosen. The selected columns are extracted for a range of rows (specified by starting and ending indices within 501 rows) as defined in the configuration and normalized using the min-max normalization formula

$${x}_{norm} = \frac{x - {x}_{min}}{{x}_{max} - {x}_{min}} .$$

The normalized columns are appended as single data point to the input data. Additionally, if a configuration specifies differentiating lengths by speaker, both the speaker label and length are concatenated as single data point to the output data; else, only the length is used. Both input and output datasets are split into training, validation, and testing sets based on the ratios specified in the configuration. The output data is then one-hot encoded to convert categorical values into numerical form.

A supervised classification neural network was developed using the Keras sequential network framework. The base network consists of four Dense layers; the first and the third layer output 128 channels and the second layer outputs 256 channels with Relu activation function. The final layer uses Softmax for obtaining the label with the highest probability in one-hot-encoding.

The neural network was trained using categorical cross-entropy as the loss function, which is well-suited for multi-class classification tasks. The Adam optimizer with default Keras parameters, known to a person having ordinary skill in the art, was employed for optimization. A batch size of 32 was used, and the initial training was conducted over epochs to allow the network to reach its full potential and observe overfitting trends through validation accuracy. Based on these results, the optimal number of epochs was identified, and the network was retrained using the updated epoch count. This approach effectively implemented a manual early-stopping procedure.

The network was evaluated on the test data to assess final accuracy, precision, and recall using the following formulas:

$$Accuracy = \frac{True positive + True Negative}{Total cases} , Precicion = \frac{True Positive}{True Positive + False Positive} , and Recall = \frac{True Positive}{True Positive + False Negative} .$$

A “True Positive” refers to a prediction where the network correctly identifies a positive case. For example, True Positive (TP) for class “5 mm” is where the network correctly classifies a “5 mm” as a “5 mm.” A “True Negative” indicates that the network correctly identifies a negative case. For example, True Negative (TN) for class “5 mm” is where the network correctly identifies a length that is not a “5 mm” (e.g., a “6 mm” or “9 mm”). A “False Positive” occurs when the network incorrectly classifies a negative case as positive, and a “False Negative” arises when the network incorrectly classifies a positive case as negative. For example, False Positive (FP) for class “5 mm” is where the network incorrectly classifies e.g., “6 mm” or “9 mm” as a “5 mm.” False Negative (FN) for class “5 mm” is a case where the network incorrectly classifying the “5 mm” as, e.g., a “6 mm” or “9 mm.” A positive case is where the network predicted a “correct” answer. A negative case is where the network predicted an “incorrect” answer.

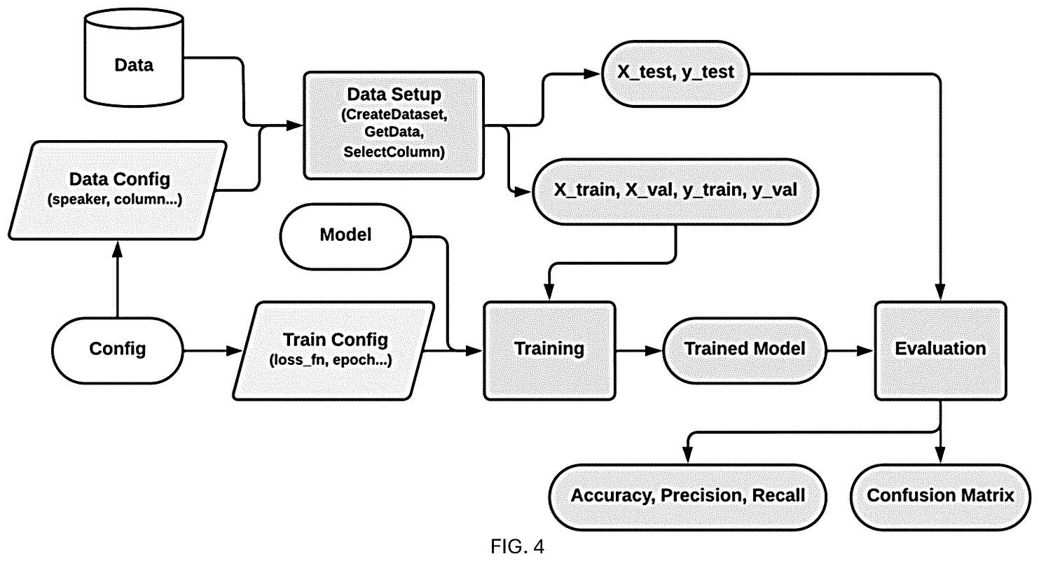

Additionally, a confusion matrix of the network's performance on the test set was plotted to visualize the results. FIG. 4 shows the flow of the network training and evaluation processes.

Phase and Magnitude were selected for the columns of input data, and the entire row was used for each column. The data was split into 60% training data, 20% validation data, and 20% testing data. Lengths for the target/output label were [“5”, “8”, “9”, “11”, “14”, “17”, “20”, “23”, “24”, “26”, “29”, “39”, “Blocked”, and “Open”], and all speaker groups A, B, C, and D were used.

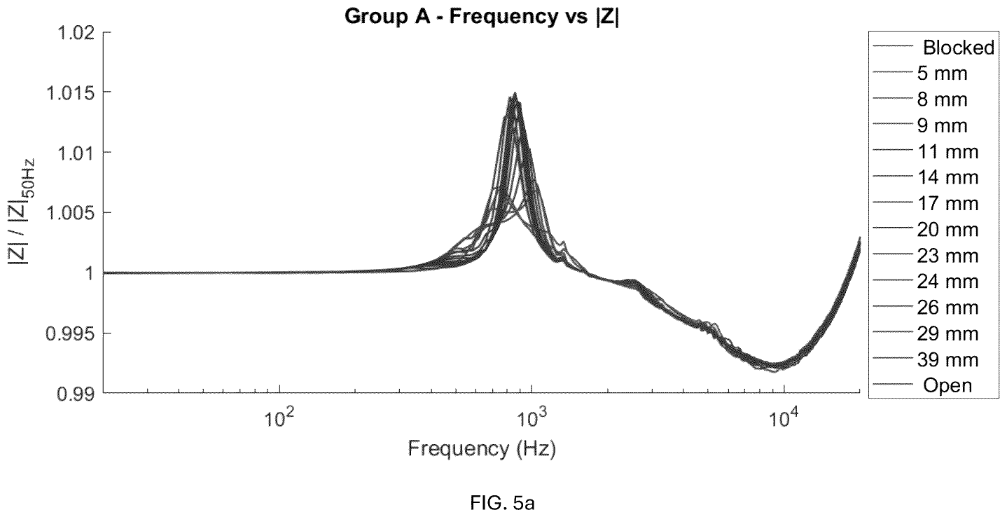

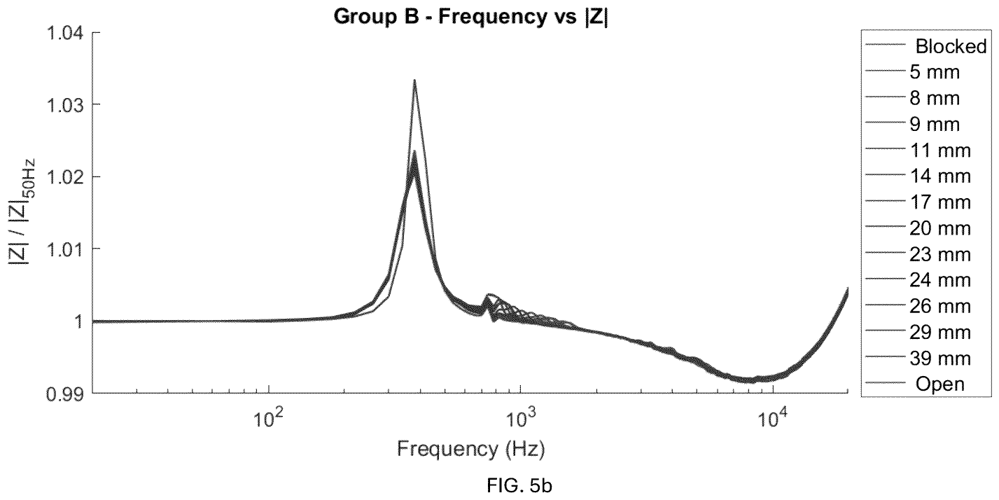

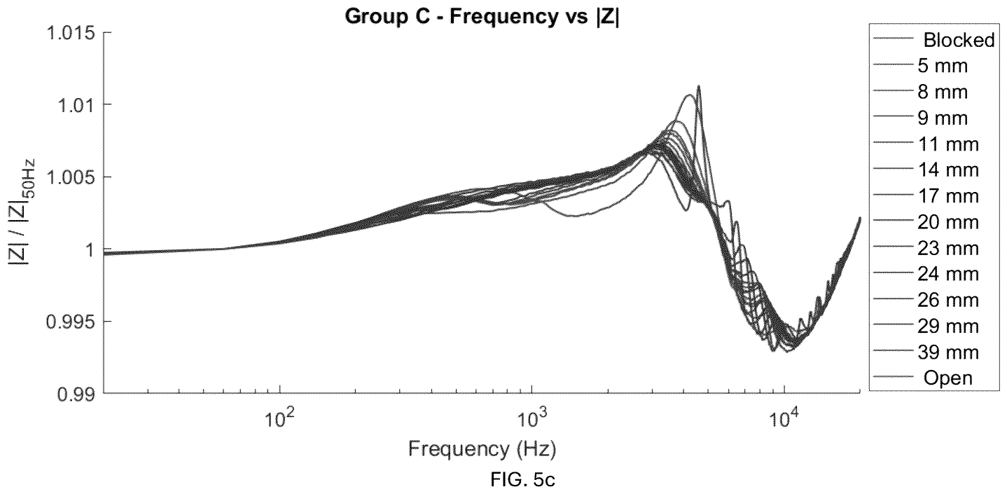

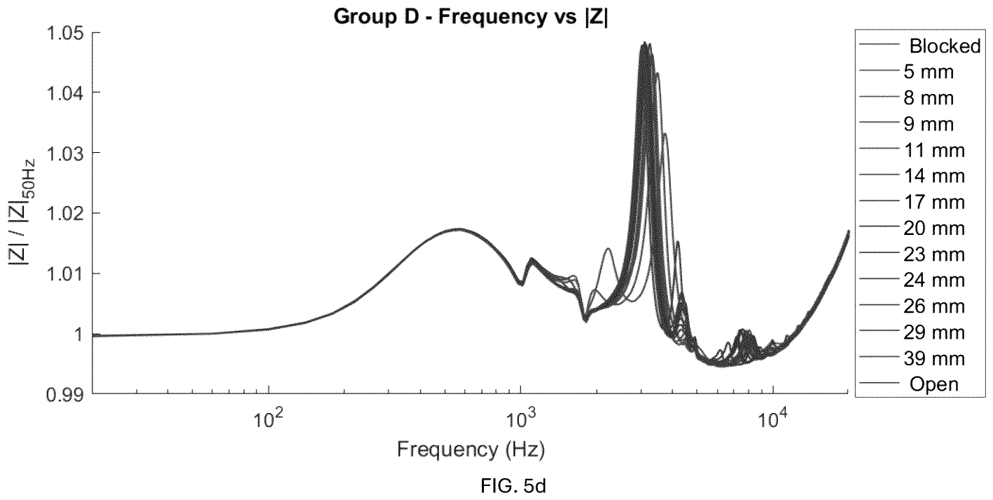

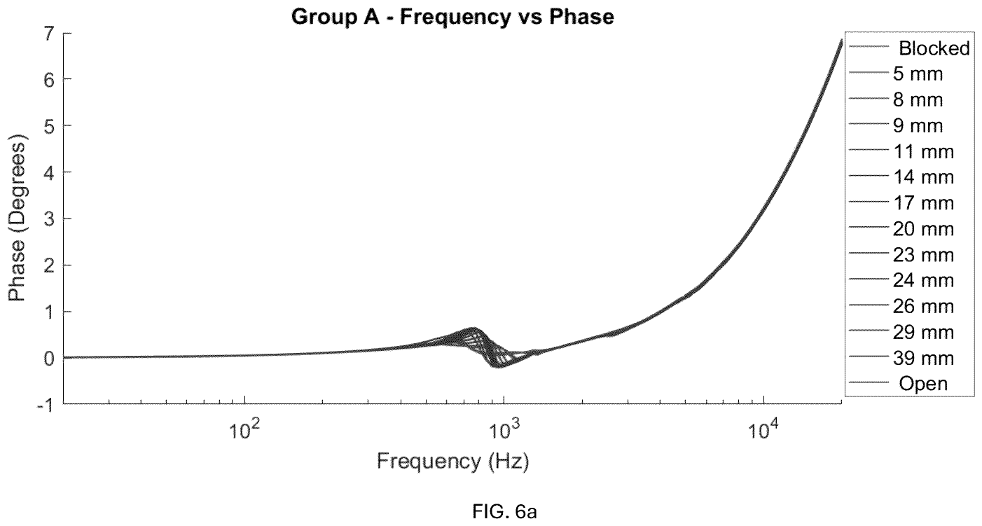

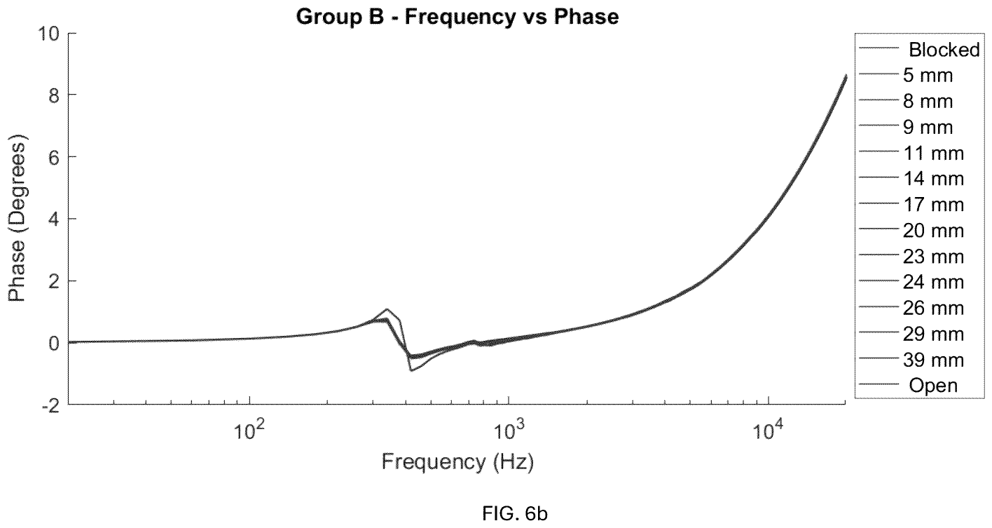

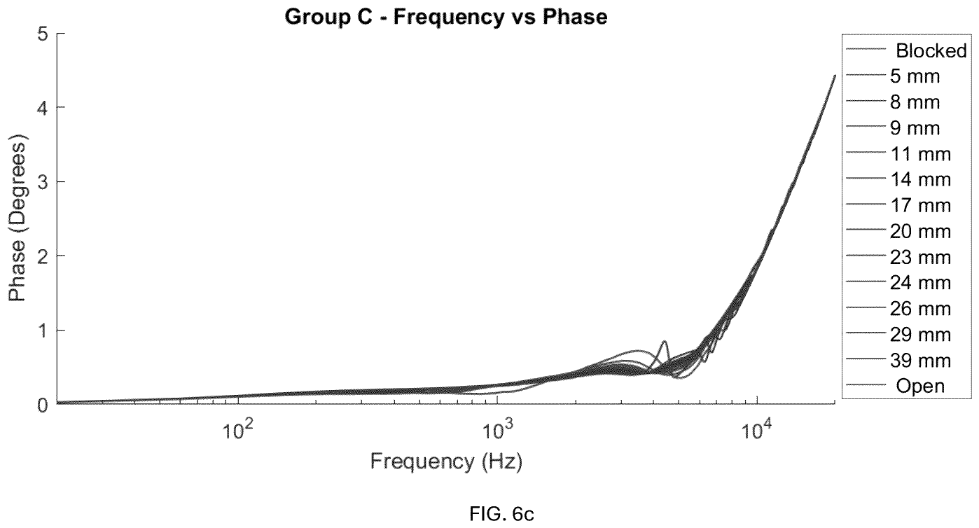

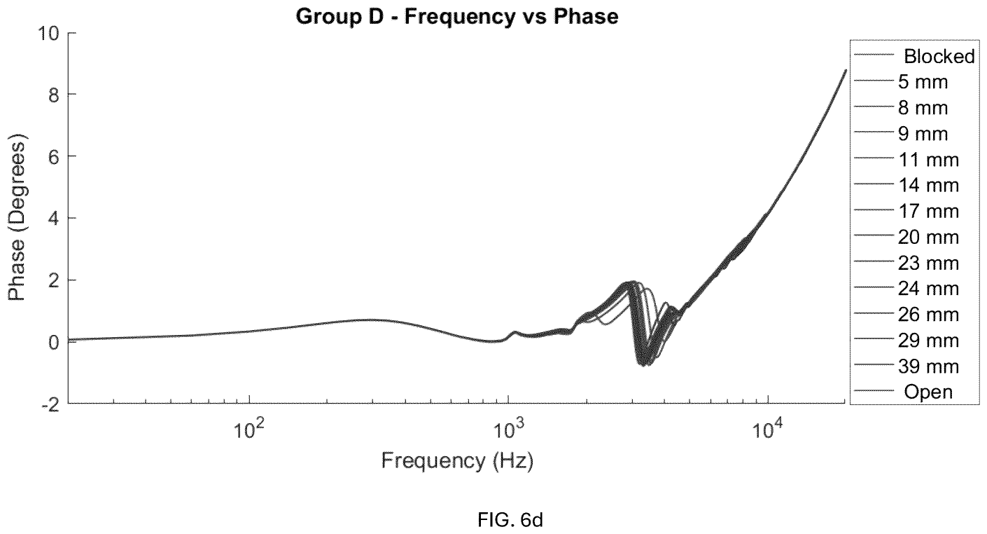

The electrical impedance data collected for each speaker under different length conditions is averaged and presented in FIGS. 5a-5d (magnitude vs. frequency graphs for various speaker groups shown in Table 1) and FIGS. 6a-6d (phase vs. frequency graphs for various speaker groups shown in Table 1), illustrating the magnitude and phase responses across frequencies, respectively. Each line is normalized to the data at the lowest measurement frequency point (20 Hz) to enhance relative comparisons across conditions and reduce potential systematic errors caused by equipment or environmental factors. By establishing a common reference point, the analysis emphasizes impedance variations with frequency rather than absolute values, allowing trends, anomalies, and frequency-specific behaviors to become more apparent. The data at 20 Hz exhibited a variation of 3-5% across 100 datasets for each condition. Length prediction results based on each speaker and results independent of the type of speaker are presented next.

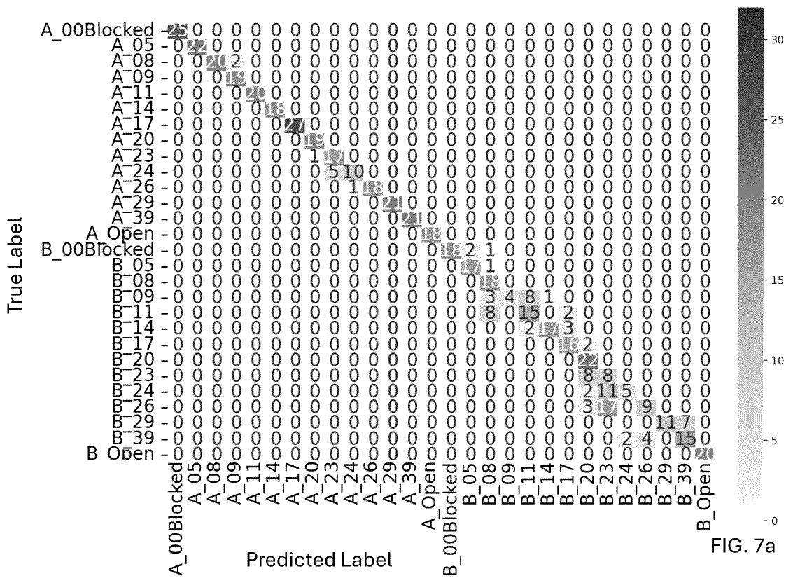

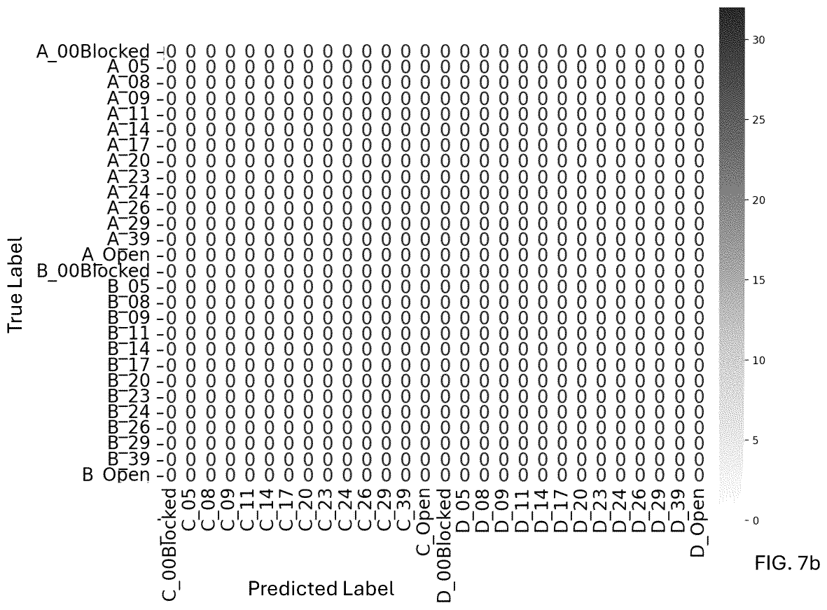

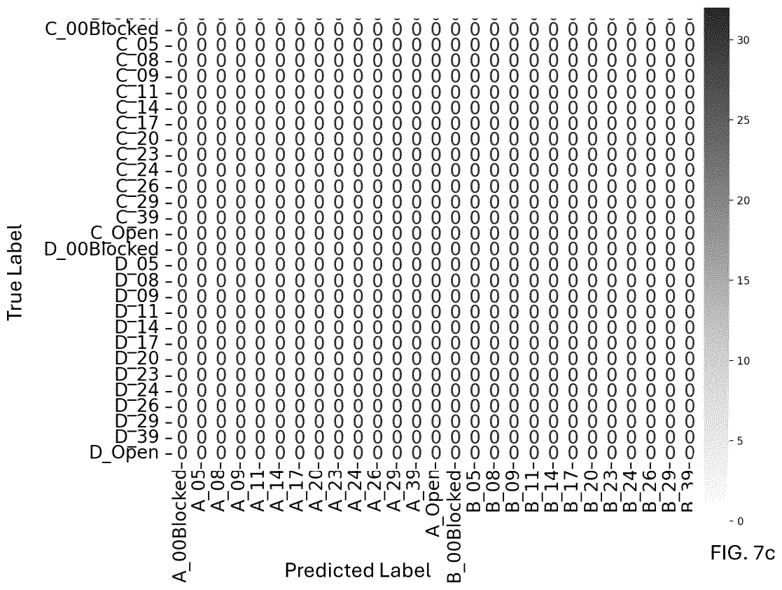

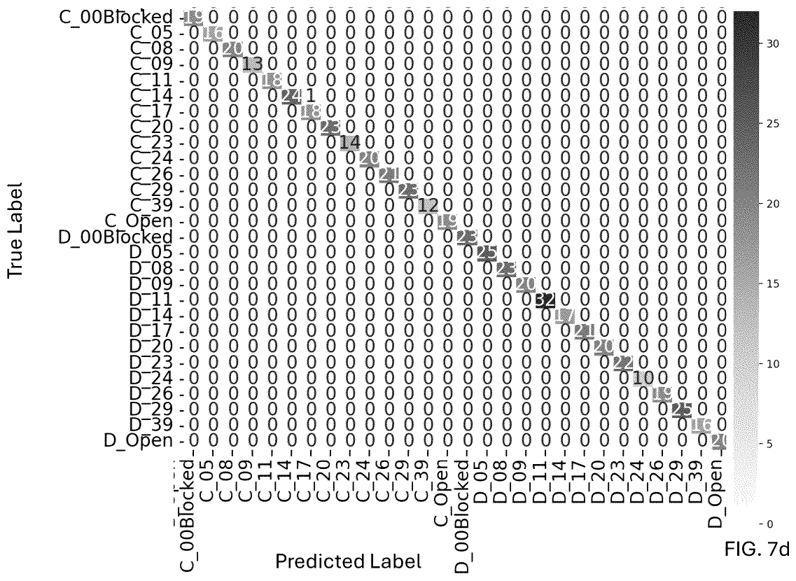

The network was trained with 110 epochs for the dataset that differentiated speaker labels in the output. The test accuracy of the network was 0.913, with precision of 0.932 and recall of 0.913. The “Speaker and Length” column in Table 3 summarizes the evaluation metrics for this result. Length refers to insertion depth. And the confusion matrix of this network's performance on the test set is shown in FIGS. 7a-7d which are graphs of true labels vs. predicted labels showing accuracy of the network.

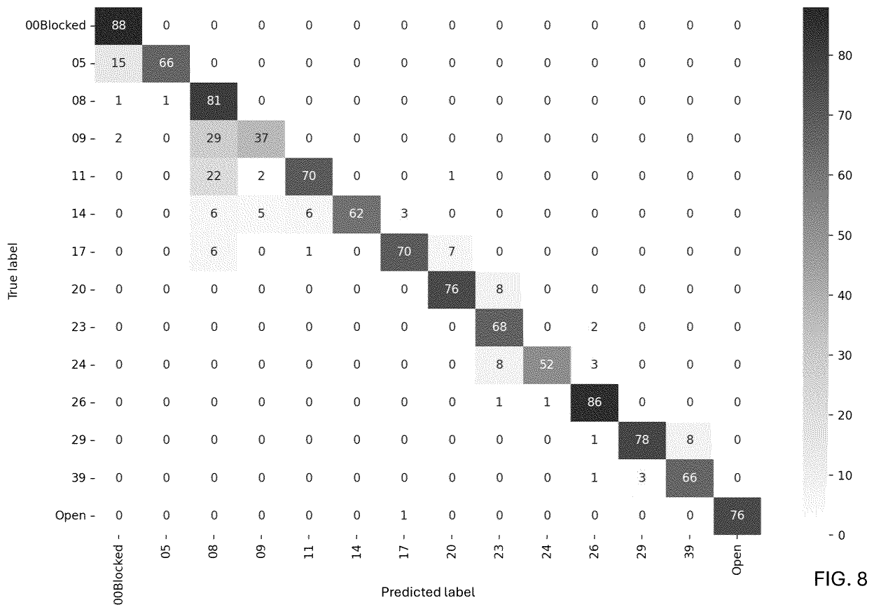

The network was trained with 100 epochs for the dataset that only has length in the output label. The test accuracy of the network was 0.871, with precision of 0.896 and recall of 0.869. The “Only Length” column in Table 3 summarizes the evaluation metrics for this result. Length refers to insertion depth. And the confusion matrix of the network's performance on the test set is shown in FIG. 8 which is a graph of true label vs. predicted label.

TABLE 3
Metric comparison for speaker and/or length identifiers

| | Speaker and | Only |
|---|---|---|
| | Length | Length |
| Epoch | 110 | 100 |
| Accuracy | 0.913 | 0.871 |
| Precision | 0.932 | 0.896 |
| Recall | 0.913 | 0.869 |

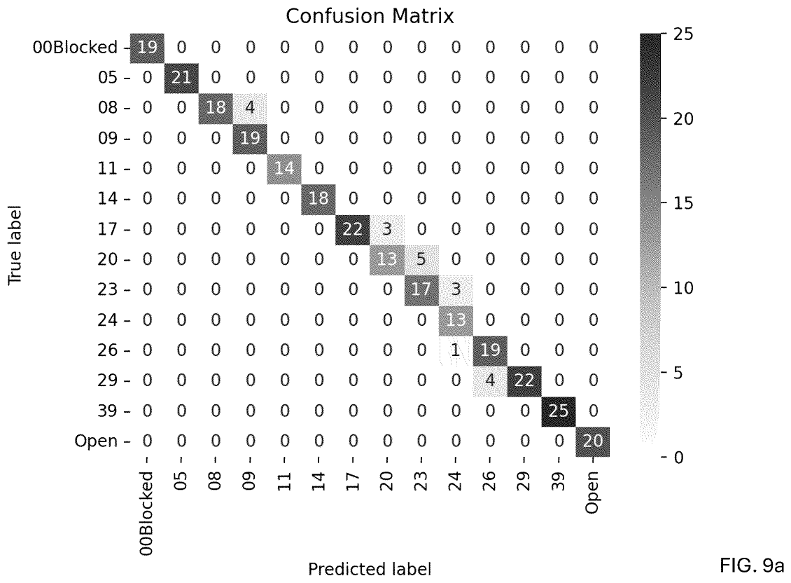

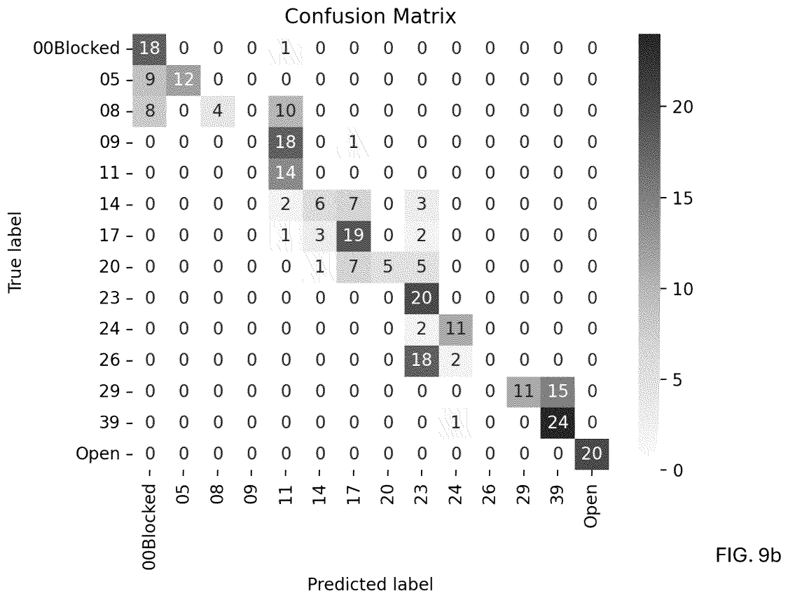

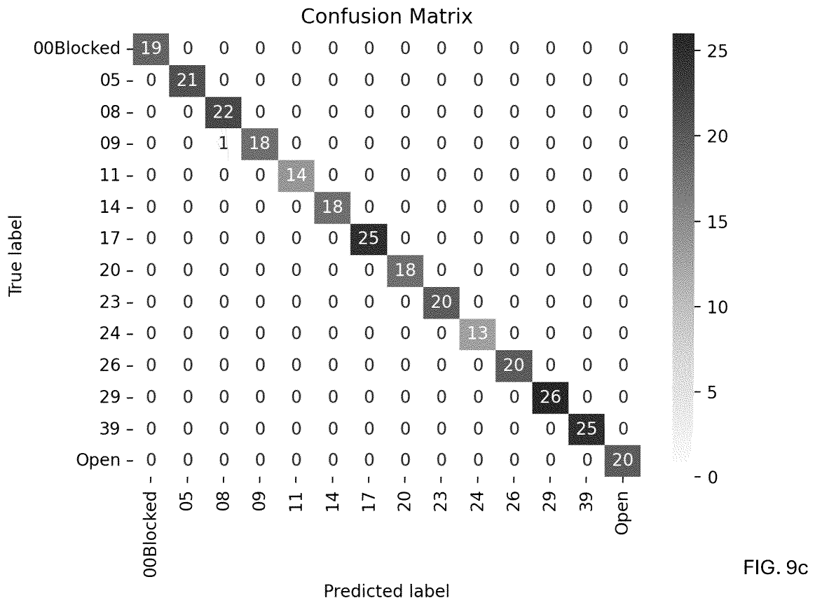

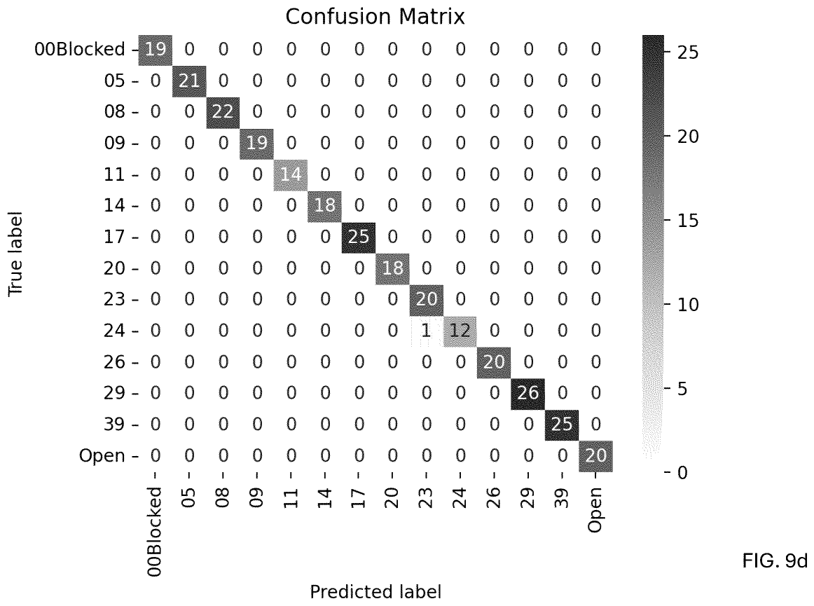

Each speaker has unique characteristics that affect the results when all data is trained together. In this trial, the network was trained on individual speaker data to assess performance for each speaker, with the goal of identifying ways to improve overall network performance. As summarized in Table 4, the network trained on speaker A dataset with 125 epochs resulted in a test accuracy of 0.929, precision of 0.929, and recall of 0.933. The network trained on speaker B dataset with 110 epochs resulted in a test accuracy of 0.586, precision of 0.627, and recall of 0.593. The network trained on speaker C dataset with 50 epochs resulted in a test accuracy of 0.996, precision of 0.997, and recall of 0.996. The network trained on speaker D dataset with 50 epochs resulted in a test accuracy of 0.996, precision of 0.997, and recall of 0.994. The network trained on speaker C and D dataset exhibited nearly 1.0 accuracy and exceeded the performance of the network with all speaker datasets. The network trained on A dataset performed almost the same as the network trained on all speakers with speaker differentiation. The network trained on B dataset led to the least accuracy and performed worse than the network with all speaker datasets. The confusion matrix of individual results is shown in FIGS. 9a-9d which are graphs of true label vs. predicted label for speaker groups A-D, respectively. It should be noted that by using a frequency cropping technique, i.e., reducing the range of 20 Hz-20,000 Hz to a smaller subset, e.g., 619 Hz-2018 Hz, the network's performance improved significantly. For example, for speaker B group, a network accuracy of 0.897, precision of 0.917, and recall of 0.916 was achieved as compared to 0.586 (not using percentages for these numbers).

An intriguing finding of the present disclosure is the ability of a speaker to sense acoustic changes, a function typically not associated with its conventional role as an actuator. These acoustic changes are reflected in the electrical terminals of the device, enabling the capture of acoustic variations through relatively simple experimental setups. This insight opens up new possibilities for repurposing speakers as sensors, significantly expanding their utility beyond traditional applications.

The shift of the electrical impedance peak frequency to lower values when the additional acoustic volume is attached to an electroacoustic transducer, such as a speaker, is a direct result of the coupling between the system's mechanical resonance and the attached acoustic load. In such systems, the resonance frequency (fᵣ) is determined by the interplay between the diaphragm's mass (Mₜₒₜₐₗ), the system's compliance (Cₜₒₜₐₗ), and the external acoustic load. The relationship is given by:

$${f}_{r} = \frac{1}{2 π \sqrt{{M}_{total} {C}_{total}}} .$$

When the acoustic volume (V) increases, the acoustic compliance (Cₐ) also increases because compliance is directly proportional to volume:

$${C}_{a} = \frac{V}{ρ {c}^{2}} ,$$

where ρ is the air density and c is the speed of sound. This increase in compliance reduces the overall stiffness of the system, thereby increasing the total compliance (Cₜₒₜₐₗ) and thus lowering the resonance frequency. At this new, lower resonance frequency, the transducer diaphragm exhibits maximum vibrational amplitude, which in turn causes the motional impedance—representing the mechanical response reflected in the electrical domain—to peak.

The electrical impedance peak typically occurs near the mechanical resonance frequency, as the system's reactance components-mass reactance (Xₘ=WMₜₒₜₐₗ) and compliance reactance (X_{c}=1/ωCₜₒₜₐₗ)—cancel each other at this point. This cancellation leaves only the resistive components (Rₑ+Rₘ) to dominate, wherein Rₑ: Represents the resistance within the electrical port-this is the portion of impedance that specifically accounts for energy dissipation in the electrical part of the system (e.g., in wires or components like resistors); and Rₘ: Represents the resistive component in the mechanical (acoustic) port—this term describes the resistance associated with the mechanical or acoustic elements, which could be due to the internal friction of a mechanical system, such as air resistance or friction within a diaphragm, that dissipates energy in the form of heat. This cancellation behavior has been well-documented in electroacoustic theory. For instance, in piezoelectric ceramics, the impedance as a function of frequency shows a distinct peak at the resonance frequency, reflecting the system's maximum efficiency in converting electrical energy into mechanical motion. Similarly, in loudspeakers, the impedance curve peaks at resonance, indicating the point where the diaphragm vibrates most efficiently and the system transitions between stiffness-controlled and mass-controlled regions. Therefore, as compliance increases with larger acoustic volumes, the mechanical resonance frequency shifts to a lower value, and the electrical impedance peak follows.

Notably, this nonlinear phenomenon—where the resonance frequency and electrical impedance peak shift in response to changes in acoustic load—exhibits distinct and consistent patterns. Data-driven approaches, such as dense neural networks (DNNs), are particularly well-suited for detecting and predicting such patterns due to their capacity to model nonlinear relationships, uncover hierarchical feature combinations, and generalize across diverse datasets.

Specifically, a DNN excels in capturing the complex, nonlinear dependencies characteristic of electroacoustic systems. For example, the relationship between acoustic volume, compliance, and resonance frequency involves highly nonlinear dynamics that are difficult to represent with conventional models. By utilizing nonlinear activation functions such as ReLU or sigmoid, DNNs can effectively learn these intricate relationships and provide accurate predictions of system behavior. Furthermore, their ability to construct hierarchical representations allows them to combine input features—such as acoustic volume and frequency response—into progressively complex patterns, enabling precise predictions of impedance behavior across varying conditions. Consequently, DNNs represent a robust and versatile tool for understanding and predicting the behavior of electroacoustic systems under different configurations, offering potential breakthroughs in the design and optimization of transducers.

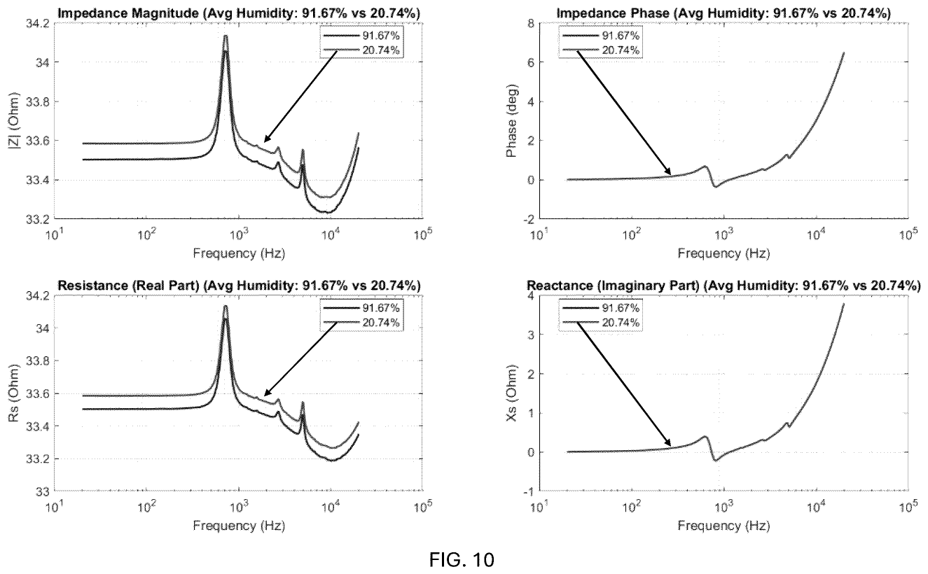

While a significant amount of discussion has been provided above with respect to insertion depth, it should be noted that other cavity parameters including relative humidity and temperature of air between the transducer (i.e., the sound probe of the transducer) and a termination body in the cavity can also affect the impedance measurements. Thus, by measuring impedance, the neural network discussed herein can also be used to predict other such parameters (i.e., temperature and relative humidity). For example, by adding water vapor to the air inside the cavity, thus changing the relative humidity between about 20% to about 92%, a significant change in impedance measurements can be observed. This change is shown in FIG. 10 which provides graphs of magnitude and phase of the impedance measurements (resulting from real part, i.e., resistance, R; and the imaginary part, i.e., the reactance, X), for these two levels of relative humidity. The data shows humidity changes are noticeable in the real part mostly. The real part of the impedance is generally more significantly affected by changes in humidity, as humidity influences the damping, viscosity, and frictional properties of materials, which are directly linked to the resistive component.

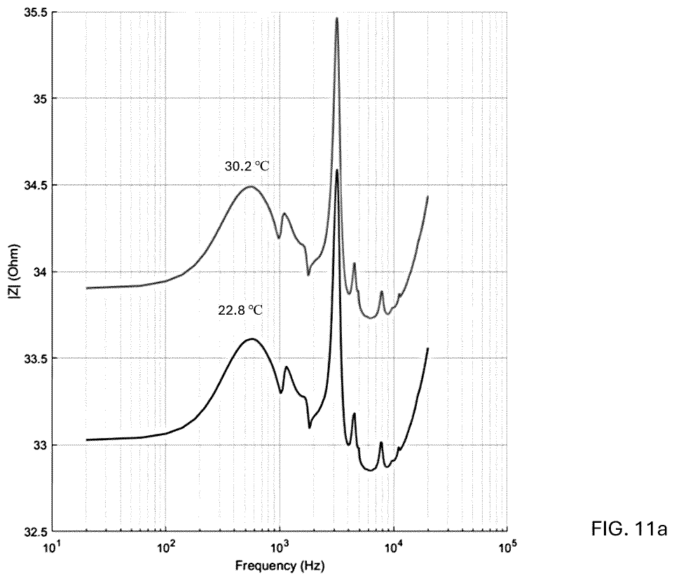

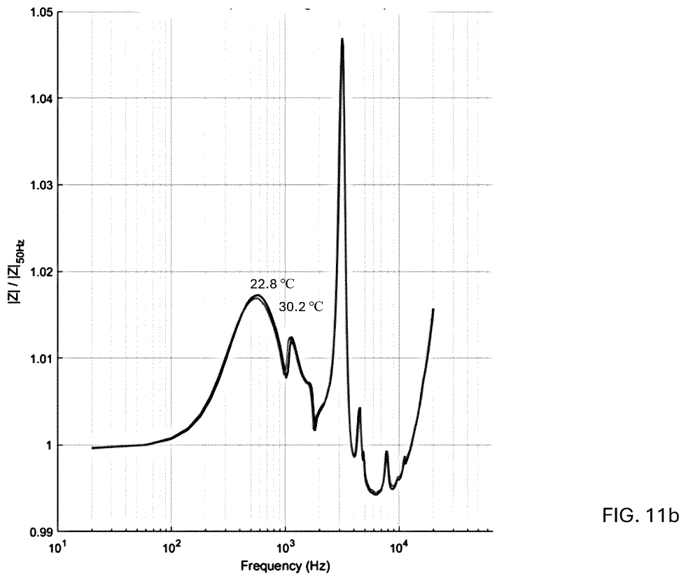

Similarly, temperature of the air between the sound probe of the speaker and the termination body of the cavity can also result in measurable differences in the measured impedance. Referring to FIGS. 11a and 11b, graphs of magnitude and phase, respectively, of the measured impedance for two different temperatures for 22.8° C. and 30.2° C. Similar to relative humidity while magnitude is significantly affected, phases experience little effect from changes in temperature.

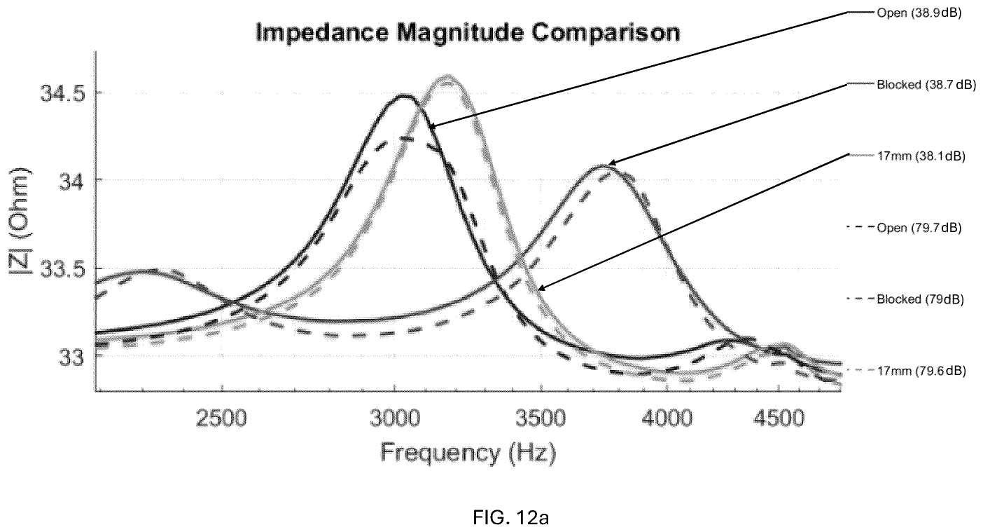

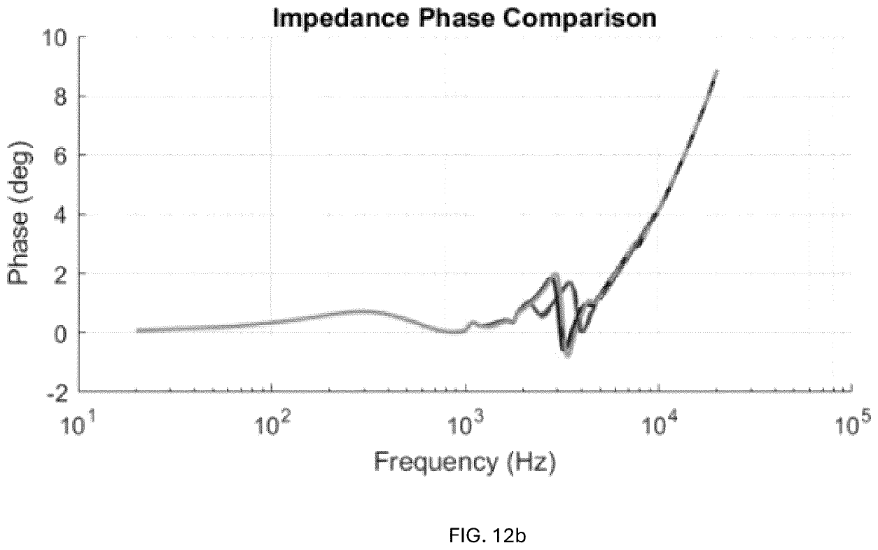

Additionally, outside ambient noise may be a concern when measuring impedance in order to correlate impedance measurements to various cavity parameters (i.e., insertion depth, temperature, and humidity). A study was conducted in order to determine effect of outside ambient noise. The results are provided in FIGS. 12a and 12b which provide magnitude and phase of impedance measurements, respectively, under various conditions (open, blocked, and an insertion depth of 17 mm) for ambient noise of about 39 dB and about 79 dB. No significant change in impedance measurements were observed in presence of outside ambient noise.

Those having ordinary skill in the art will recognize that numerous modifications can be made to the specific implementations described above. The implementations should not be limited to the particular limitations described. Other implementations may be possible.

1. A method of measuring characteristics of a cavity using an electroacoustic transducer, comprising:
inserting an electroacoustic transducer having at least two electrical terminals and a sound port into a proximal end of a cavity having a distal end defining a termination body, wherein the electroacoustic transducer is configured to i) operate in a speaker mode thereby generating sound waves when an electrical signal is provided across the at least two electrical terminals, and ii) operate in a sensor mode when measuring impedance across the at least two electrical terminals;
operating the electroacoustic transducer in the speaker mode by applying an electrical signal having a predetermined frequency range across the at least two electrical terminals;
operating the electroacoustic transducer in the sensor mode by measuring impedance across the at least two electrical terminals in response to the applied electrical signal;
providing the measured impedance to a neural network, wherein the neural network has been a priori trained to correlate impedance measurements of the electroacoustic transducer to cavity characteristics; and
predicting cavity characteristics based on output of the neural network.

2. The method of claim 1, wherein the predetermined frequency range is between 20 Hz and 20,000 Hz.

3. The method of claim 1, wherein the cavity characteristics includes insertion depth representing distance between the sound port of the electroacoustic transducer and the termination body.

4. The method of claim 3, wherein the insertion depth ranges from about 1 mm to about 50 mm.

5. The method of claim 1, wherein the cavity characteristics includes temperature of air between the sound port of the electroacoustic transducer and the termination body.

6. The method of claim 5, wherein the temperature of air ranges from about 20° C. to about 40° C.

7. The method of claim 1, wherein the cavity characteristics includes relative humidity of air between the sound port of the electroacoustic transducer and the termination body.

8. The method of claim 7, wherein the relative humidity of air ranges from about 10% to about 90%.

9. The method of claim 1, wherein the neural network is a convolutional neural network including an input layer, an output layer, and at least one hidden layer, wherein input to the convolutional neural network is an image representing impedance measurements.

10. The method of claim 1, wherein the neural network is a dense neural network including an input layer, an output layer, and at least one hidden layer, wherein input to the dense neural network is a dataset representing raw impedance measurements.

11. A system for measuring characteristics of a cavity using an electroacoustic transducer, comprising:
an electroacoustic transducer having at least two electrical terminals and a sound port, wherein the electroacoustic transducer is configured to i) operate in a speaker mode thereby generating sound waves when providing an electrical signal across the at least two electrical terminals, and ii) operate in a sensor mode when measuring impedance across the at least two electrical terminals; and
a processor executing software maintained in a non-transitory memory, the processor configured to:
generate a signal that is applied across the at least two electrical terminals of the electroacoustic transducer when the electroacoustic transducer is inserted into a proximal end of a cavity having a distal end defining a termination body, wherein the electroacoustic transducer is operated in the speaker mode,
measure impedance across the at least two electrical terminals of the electroacoustic transducer, wherein the electroacoustic transducer is operated in the sensor mode in response to the applied signal,
provide the measured impedance to a neural network, wherein the neural network has been a priori trained to correlate impedance measurements of the electroacoustic transducer to cavity characteristics, and
predict cavity characteristics based on output of the neural network.

12. The system of claim 11, wherein the predetermined frequency is between 20 Hz and 20,000 Hz.

13. The system of claim 11, wherein the cavity characteristics includes insertion depth representing distance between the sound port of the electroacoustic transducer and the termination body.

14. The system of claim 13, wherein the insertion depth ranges from about 1 mm to about 50 mm.

15. The system of claim 11, wherein the cavity characteristics includes temperature of air between the sound port of the electroacoustic transducer and the termination body.

16. The system of claim 15, wherein the temperature of air ranges from about 20° C. to about 40° C.

17. The system of claim 11, wherein the cavity characteristics includes relative humidity of air between the sound port of the electroacoustic transducer and the termination body.

18. The system of claim 17, wherein the relative humidity of air ranges from about 10% to about 90%.

19. The system of claim 11, wherein the neural network is a convolutional neural network including an input layer, an output layer, and at least one hidden layer, wherein input to the convolutional neural network is an image representing impedance measurements.

20. The system of claim 11, wherein the neural network is a dense neural network including an input layer, an output layer, and at least one hidden layer, wherein input to the dense neural network is a dataset representing raw impedance measurements.
